(19) United States
(12) Patent Application Publication
(10) Pub. No.: US 2022/0285139 A1
(43) Pub. Date: Sep. 8, 2022

(54) APPARATUS FOR TREATING SUBSTRATE AND SUBSTRATE TREATING METHOD

(71) Applicant: SEMES CO., LTD., Cheonan-si (KR)

(72) Inventors: Jung Hoon PARK, Sejong-si (KR); Yun Sang KIM, Seongnam-si (KR); Min Sung JEON, Osan-si (KR); Soon-Cheon CHO, Pyeongtaek-si (KR); Sung Min CHOI, Osan-si (KR); Jin Hee HONG, Hwaseong-si (KR)

(73) Assignee: SEMES CO., LTD., Cheonan-si (KR)

(21) Appl. No.: 17/682,029

(22) Filed: Feb. 28, 2022

(30) Foreign Application Priority Data
Mar. 2, 2021 (KR) 10-2021-0027367

(51) Int. Cl. H01J 37/32

(52) U.S. Cl. CPC H01J 37/32724; H01J 37/32568; H01J 37/32082; H01J 37/3244; H01J 2237/2007; H01J 2237/334; H01L 21/6831

(57) ABSTRACT

The inventive concept provides a substrate treating apparatus. The substrate treating apparatus comprises a chamber having a treating space therein; a support unit placed within the treating space and supporting a substrate; and a plasma generating unit for generating a plasma from a process gas supplied to the treating space, and wherein the plasma generating unit comprising: a first electrode; and a second electrode facing the first electrode, the second electrode made of a material capable of transmitting electromagnetic waves.

### CROSS-REFERENCE TO RELATED APPLICATIONS

A claim for priority under 35 U.S.C. § 119 is made to Korean Patent Application No. 10-2021-0027367 filed on Mar. 2, 2021, in the Korean Intellectual Property Office, the entire contents of which are hereby incorporated by reference.

### BACKGROUND

Embodiments of the inventive concept described herein relate to an apparatus for treating a substrate and a method for treating the substrate using a plasma.

During a semiconductor device manufacturing process, a desired pattern is formed on a substrate by performing various processes such as photolithography, etching, ashing, ion implantation, thin film deposition, cleaning, etc. Among them, the etching process is a process of removing selectively at least a portion of a film formed on the substrate, and wet etching and dry etching are used.

Among them, an etching device using a plasma is used for dry etching. In general, in order to form the plasma, an electromagnetic field is generated in an inner space of the chamber, and the electromagnetic field excites a process gas provided in the chamber into a plasma state.

The plasma refers to an ionized gas state comprising of ions, electrons, radicals, or the like. The plasma is generated by a very high temperature, a strong electric field, or an RF electromagnetic field. In the semiconductor device manufacturing process, an etching process is performed using the plasma.

In the method of raising a temperature of the substrate in the substrate treating apparatus using the plasma, the temperature of the substrate is raised by using a heating means (a heating wire) of a substrate support member on which the substrate is placed.

However, in the substrate heating method using the heating wire, it takes a long time to raise the temperature of the substrate, and it is difficult to uniformly heat the entire substrate.

### SUMMARY

Embodiments of the inventive concept provide a substrate treating apparatus and a substrate treating method for quickly heating a substrate in a substrate treating process using a plasma.

Embodiments of the inventive concept also provide a substrate treating apparatus and a substrate treating method for conveniently changing a heating source and controlling a temperature of a substrate.

The technical objectives of the inventive concept are not limited to the above-mentioned ones, and the other unmentioned technical objects will become apparent to those skilled in the art from the following description.

The inventive concept provides a substrate treating apparatus. The substrate treating apparatus includes a chamber having a treating space therein; a support unit placed within the treating space and supporting a substrate; and a plasma generating unit for generating a plasma from a process gas supplied to the treating space, and wherein the plasma generating unit comprises: a first electrode; and a second electrode facing the first electrode, the second electrode made of a material capable of transmitting electromagnetic waves.

In an embodiment, the substrate treating apparatus comprises a heating unit for heating the substrate.

In an embodiment, the heating unit comprises a heating device using a thermal radiation.

In an embodiment, the heating device is any one of an IR lamp, a flash lamp, a laser, or a microwave.

In an embodiment, the second electrode is provided at a top wall of the chamber, the heating unit is provided above the top wall of the chamber, and the top wall is made of a material capable of transmitting electromagnetic waves.

In an embodiment, the second electrode is provided as a showerhead type with a through-hole for supplying a reaction gas onto the substrate placed on the support unit.

In an embodiment, the second electrode is made of any one of an ITO (Indium Tin Oxide), an MnO (Manganese Oxide), a ZnO (Zinc Oxide), an IZO (Indium Zinc Oxide), an FTO, an AZO, a graphene, a CNT (Carbon Nano Tube), a metal nanowire, or a PEDOT-PSS.

The inventive concept provides a substrate treating apparatus. The substrate treating apparatus includes a chamber wherein a plasma reaction process is performed; a support unit provided at a bottom side within the chamber, holding a substrate thereon, and including a first electrode; a second electrode provided at a top side of the chamber for generating an electric field for a plasma reaction process within the chamber; and a power supply means for applying an RF power to the second electrode and/or the first electrode for generating an electric field between the second electrode and the first electrode; wherein the second electrode is made of a material capable of transmitting electromagnetic waves.

In an embodiment, the substrate treating apparatus further comprises a heating unit for heating the substrate.

In an embodiment, the heating unit comprises a heating device using a thermal radiation.

In an embodiment, the heating device is any one of an IR lamp, a flash lamp, a laser, or a microwave.

In an embodiment, the second electrode is provided at a top wall of the chamber, and the heating unit is provided above the top wall of the chamber.

In an embodiment, the top wall is made of a material capable of transmitting electromagnetic waves.

In an embodiment, the second electrode is made of any one of an ITO (Indium Tin Oxide), an MnO (Manganese Oxide), a ZnO (Zinc Oxide), an IZO (Indium Zinc Oxide), an FTO, an AZO, a graphene, a CNT (Carbon Nano Tube), a metal nanowire, or a PEDOT-PSS.

In an embodiment, the second electrode is provided as a showerhead type with a through-hole for supplying a reaction gas onto the substrate placed on the support unit.

The inventive concept provides a substrate treating apparatus. The substrate treating apparatus includes a chamber having a top wall with a transparent window and providing a plasma treating space; an electrostatic chuck provided at a bottom side of the plasma treating space, electrostatically chucking a substrate and serving as a bottom electrode; a shower-head placed below the transparent window of the top wall and above the electrostatic chuck, having a through-role for supplying a reaction gas onto the substrate placed on the electrostatic chuck, and serving as top electrode; and a heating unit placed above the transparent window of the top wall and providing a light energy for heating the substrate; wherein the showerhead is made of a material capable of transmitting electromagnetic waves provided from the heating unit.

In an embodiment, the showerhead is made of any one of an ITO (Indium Tin Oxide), an MnO (Manganese Oxide), a ZnO (Zinc Oxide), an IZO (Indium Zinc Oxide), an FTO, an AZO, a graphene, a CNT (Carbon Nano Tube), a metal nanowire, or a PEDOT-PSS.

In an embodiment, the heating device is any one of an IR lamp, a flash lamp, a laser, or a microwave.

In an embodiment, the substrate treating apparatus further comprises a power supply means for applying an RF power to the electrostatic chuck and/or the shower head for generating an electric field therebetween.

The inventive concept provides a substrate treating method in a substrate treating apparatus. The substrate treating method in a substrate treating apparatus includes comprising a top electrode and a bottom electrode opposing each other in a process chamber, the method comprising: heating a substrate disposed within the process chamber with a heating unit adjacent the top electrode, the top electrode provided below the top wall of the process chamber and a top side of the process chamber, and the top wall and the top electrode being made of materials which are capable of transmitting electromagnetic waves such that the electromagnetic waves emitted from the heating unit pass through the top wall and the top electrode to heat a substrate located below the top electrode and above the bottom electrode.

According to an embodiment of the inventive concept, a substrate may be quickly heated using a thermal radiation.

According to an embodiment of the inventive concept, changing a heating source and controlling a temperature of a substrate is convenient.

The effects of the inventive concept are not limited to the above-mentioned ones, and the other unmentioned effects will become apparent to those skilled in the art from the following description.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a view illustrating a substrate treating apparatus according to an embodiment of the inventive concept;

FIG. 2 is a view illustrating another substrate treating apparatus according to an embodiment of the inventive concept;

FIG. 3 is a view illustrating a heating unit of FIG. 2.

### DETAILED DESCRIPTION

The inventive concept may be variously modified and may have various forms, and specific embodiments thereof will be illustrated in the drawings and described in detail. However, the embodiments according to the concept of the inventive concept are not intended to limit the specific disclosed forms, and it should be understood that the present inventive concept includes all transforms, equivalents, and replacements included in the spirit and technical scope of the inventive concept. In a description of the inventive concept, a detailed description of related known technologies may be omitted when it may make the essence of the inventive concept unclear.

It should be understood that, although the terms first, second, third, etc. may be used herein to describe various elements, regions, layers and/or sections, these elements, regions, layers, and/or sections should not be limited by these terms. These terms are only used to distinguish one element, region, layer, or section from another region, layer, or section. Thus, a first element, region, layer, or section discussed below could be termed a second element, region, layer, or section without departing from the teachings of example embodiments.

In an embodiment of the inventive concept, a substrate treating apparatus for etching a substrate using a plasma will be described. However, the technical features of the inventive concept are not limited thereto, and may be applied to various kinds of apparatus that process the substrate W using the plasma. The inventive concept may be applied to any kinds of apparatus which performs any treatment onto the substrate supported by a supporting unit.

In addition, in an embodiment of the inventive concept, an electrostatic chuck will be described as an example of a support unit. However, the inventive concept is not limited thereto, and the support unit may support the substrate by mechanical clamping or by vacuum.

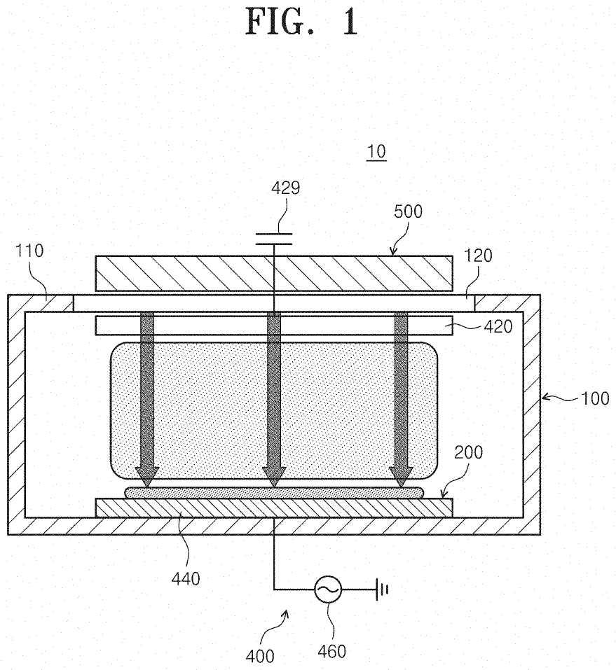

FIG. 1 is a view illustrating a substrate treating apparatus according to an embodiment of the inventive concept.

Referring to FIG. 1, the substrate treating apparatus 10 may include a process chamber 100, a support unit 200, a plasma generating unit 400, and a heating unit 500. The substrate treating apparatus processes a substrate W using a plasma.

The process chamber 100 has an inner space for performing a process therein. The support unit 200 is positioned in a bottom region of the inner space of the process chamber 100. The substrate is placed on the support unit 200.

The plasma generating unit 400 generates the plasma from a process gas above the support unit 200 in the process chamber 100. The plasma generating unit 400 may include a first electrode 420, a second electrode 440, and a high frequency power supply 460. The first electrode 420 and the second electrode 440 may be provided to face each other in an up/down direction. The second electrode 440 may be provided in the support unit 200. That is, the support unit 200 may function as an electrode.

The first electrode 420 may be made of a material capable of transmitting electromagnetic waves. More specifically, the first electrode 420 may be a transparent electrode through which a light energy provided from the heating unit 500 may pass and arrive at and heat the substrate. In an embodiment, the first electrode 420 may be a transparent electrode formed of an indium tin oxide (ITO) material made of an indium oxide and a tin oxide. In another embodiment, the first electrode may be any one of an MnO (Manganese Oxide), ZnO (Zinc Oxide), IZO (Indium Zinc Oxide), FTO, AZO, Graphene, CNT (Carbon Nano Tube), Metal nanowire, or a PEDOT-PSS.

The first electrode 420 may be located under a transparent window 120 provided in a top wall 110 of the process chamber 100.

According to an embodiment, the first electrode 420 may be grounded 429, and a high frequency power supply 460 may be connected to the second electrode 440. Alternatively, the high frequency power supply 460 may be connected to the first electrode 420 and the second electrode 440 may be grounded. In other embodiments, the high frequency power supply 460 may be connected to both the first electrode 420 and the second electrode 440.

The heating unit 500 may be disposed on above the transparent window 120. The heating unit 500 may be a heating device using a thermal radiation. In an embodiment, the heating unit may include IR lamps. In another embodiment, the heating unit may be any one of heat sources such as a flash lamp, a laser, or a microwave. The heating unit 500 emits the light energy, and the light energy may pass through the window 120 and the first electrode 420 to arrive at and heat the substrate W supported by the second electrode 440. Accordingly, the substrate may be rapidly heated by the light energy.

In the present embodiment, the heating unit 500 is illustrated as being disposed outside the process chamber, but is not limited thereto. In an embodiment, the heating unit 500 may be below the second electrode within the process chamber, and in this case, the second electrode may be provided with a transparent material such that the light energy from the heating unit 500 may pass through the second electrode to arrive at and heat the substrate W.

When the plasma treatment process is performed in the substrate treating apparatus 10 having the above-described configuration, the substrate may be rapidly heated by the heating unit 500. In this way, by providing the first electrode 420 as a transparent electrode (a material capable of transmitting electromagnetic waves such as light energy), the heating unit 500 for heating the substrate may be disposed outside the process chamber 100. In addition, since the heating unit 500 is provided outside the process chamber 100, maintenance (lamp replacement, output capacity changing, etc.) of the heating unit 500 may be facilitated, and damage caused by the plasma may be prevented.

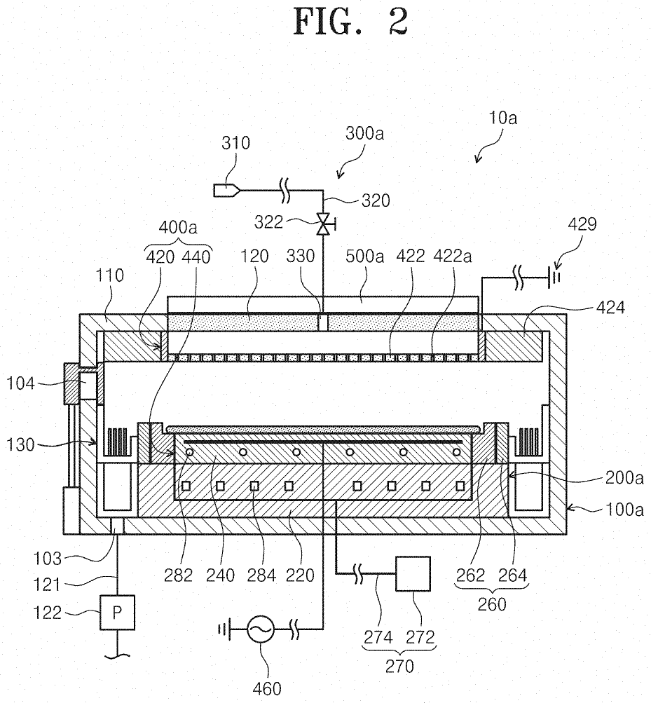

FIG. 2 is a view illustrating a substrate treating apparatus 10a according to another embodiment of the inventive concept.

Referring to FIG. 2, the substrate treating apparatus 10a may include a process chamber 100a, a support unit 200a, a gas supply unit 300a, a plasma generating unit 400a, and a heating unit 500a. The substrate treating apparatus processes the substrate W using a plasma.

The process chamber 100a has an inner space for performing a process therein. An exhaust hole 103 is formed on a bottom wall of the process chamber 100a. An exhaust hole 103 is connected to an exhaust line 121 on which a pump 122 is mounted. A reaction by-product(s) generated during the process and the gas remaining in the process chamber 100a are exhausted to the exhaust line 211 through exhaust hole 103. Accordingly, the by-product(s) may be discharged to an outside of the process chamber 100a. In addition, the inner space of the process chamber 100a is decompressed to a predetermined pressure by the exhaust process. In an embodiment, the exhaust hole 103 may be provided at a position directly communicating with a through hole 158 of a liner unit 130 to be described later.

An opening 104 is formed on a sidewall of the process chamber 100a. The opening 104 functions as a passage through which the substrate enters and exits the process chamber 100a.

The opening 104 is opened and closed by a door assembly (not shown). According to an embodiment, the door assembly (not shown) has an outer door, an inner door, and a connection plate. The outer door is provided on an outer wall of the process chamber. The inner door is provided on an inner wall of the process chamber. The outer door and the inner door are fixedly coupled to each other by the connection plate. The connection plate is provided to extend from an inside to an outside of the process chamber through the opening. A door driver moves the outer door in the up/down direction. The door driver may include a pneumatic cylinder or a motor.

A support unit 200a is positioned in a bottom region of the inner space of the process chamber 100a. The support unit 200a supports the substrate W by an electrostatic force. Unlike this, the support unit 200a may support the substrate W in various ways such as mechanical clamping.

The support unit 200a may include a support plate 210, a ring assembly 260, and a gas supply line 270. The substrate W is placed on the support plate 210. The support plate 210 has a base 220 and an electrostatic chuck 240. The electrostatic chuck 240 supports the substrate Won its top surface by an electrostatic force. The electrostatic chuck 240 is fixedly coupled onto the base 220.

The ring assembly 260 is provided with a ring shape. The ring assembly 260 is provided to surround a circumference of the support plate 210. In an embodiment, the ring assembly 260 is provided to surround a circumference of the electrostatic chuck 240. The ring assembly 260 supports an edge region of the substrate W. According to an embodiment, the ring assembly 260 has a focus ring 262 and an insulating ring 264. The focus ring 262 is provided to surround the electrostatic chuck 240 and concentrates a plasma on the substrate W. The insulating ring 264 is provided to surround the focus ring 262. Optionally, the ring assembly 260 may include an edge ring (not shown) provided in close contact with a circumference of the focus ring 262 to prevent side surfaces of the electrostatic chuck 240 from being damaged by the plasma. Unlike the above description, a structure of the ring assembly 260 may be variously changed.

The gas supply line unit 270 includes a gas supply source 272 and a gas supply line 274. The gas supply line 274 is provided between the ring assembly 260 and the support plate 210.

The gas supply line 274 supplies a gas to remove foreign substances remaining on a top surface of the ring assembly 260 or in an edge area of the support plate 210. In an embodiment, the gas may be a nitrogen gas (N₂). Optionally, other gases or cleaners may be supplied. The gas supply line 274 may be formed inside the support plate 210 to be connected between the focus ring 262 and the electrostatic chuck 240. Alternatively, the gas supply line 274 may be provided inside the focus ring 262 and bent to be connected between the focus ring 262 and the electrostatic chuck 240.

According to an embodiment, the electrostatic chuck 240 may be formed of a ceramic material, the focus ring 262 may be formed of a silicon material, and the insulating ring 264 may be formed of a quartz material. A heating member 282 and a cooling member 284 for maintaining the substrate W at a process temperature during the process may be provided in the electrostatic chuck 240 and/or the base 220. The heating member 282 may be provided as a heating wire. The cooling member 284 may be provided as a cooling line through which a refrigerant flows. According to an embodiment, the heating member 282 may be provided in the electrostatic chuck 240, and the cooling member 284 may be provided in the base 220.

The gas supply unit 300a supplies a process gas into the process chamber 100a. The gas supply unit 300a includes a gas storage unit 310, a gas supply line 320, and a gas inlet port 330. The gas supply line 320 connects the gas storage unit 310 and the gas inlet port 330. The gas supply line 320 supplies the process gas stored in the gas storage unit 310 to the gas inlet port 330. A valve 322 for opening and closing a passage or adjusting a flow rate of the fluid flowing through the passage may be installed at the gas supply line 320.

The plasma generating unit 400a generates the plasma from the process gas remaining in a discharge space. The discharge space corresponds to a portion of the inner space above the support unit 200a in the process chamber 100a. The plasma generating unit 400 may have a capacitive coupled plasma source.

The plasma generating unit 400a may include a top electrode 420, a bottom electrode 440, and a high frequency power supply 460. The top electrode 420 and the bottom electrode 440 may be provided to face each other in the up/down direction.

The top electrode 420 may be a transparent electrode through which the light energy provided from the heating unit 500a may pass. For example, the top electrode 420 may be a transparent electrode formed of an indium tin oxide (ITO) material made of an indium oxide and a tin oxide. In another embodiment, the top electrode may be any one of a MnO (Manganese Oxide), a ZnO (Zinc Oxide), an IZO (Indium Zinc Oxide), an FTO, an AZO, a Graphene, a CNT (Carbon Nano Tube), a metal nanowire, or a PEDOT-PSS.

The top electrode 420 may be located below the transparent window 120 provided in the top wall 110 of the process chamber 100a. The transparent window 120 may be made of a material capable of transmitting electromagnetic waves like the top electrode. In an embodiment, the top electrode 420 may include a shower head 422 and a ring assembly 424. The shower head 422 may be positioned to face the electrostatic chuck 240 and may be provided with a diameter greater than that of the electrostatic chuck 240. The shower head 422 may be provided as the top electrode. A plurality of holes 422a for spraying a gas are formed at the shower head 422. The ring assembly 424 is provided to surround the shower head 422. The ring assembly 424 may be provided to be in close contact with the shower head 422. According to an embodiment, the shower head 422 may be provided as the top electrode. The bottom electrode 440 may be provided within the electrostatic chuck 240.

According to an embodiment, the top electrode 420 may be grounded 429, and a high frequency power supply 460 may be connected to the bottom electrode 440. In some embodiments, the high frequency power supply 460 may be connected to the top electrode 420 and the bottom electrode 440 may be grounded. In some embodiments, the high frequency power supply 460 may be connected to both the top electrode 420 and the bottom electrode 440. According to an embodiment, the high frequency power supply 460 may continuously apply a power to the top electrode 420 and/or the bottom electrode 440 or may apply a pulse power.

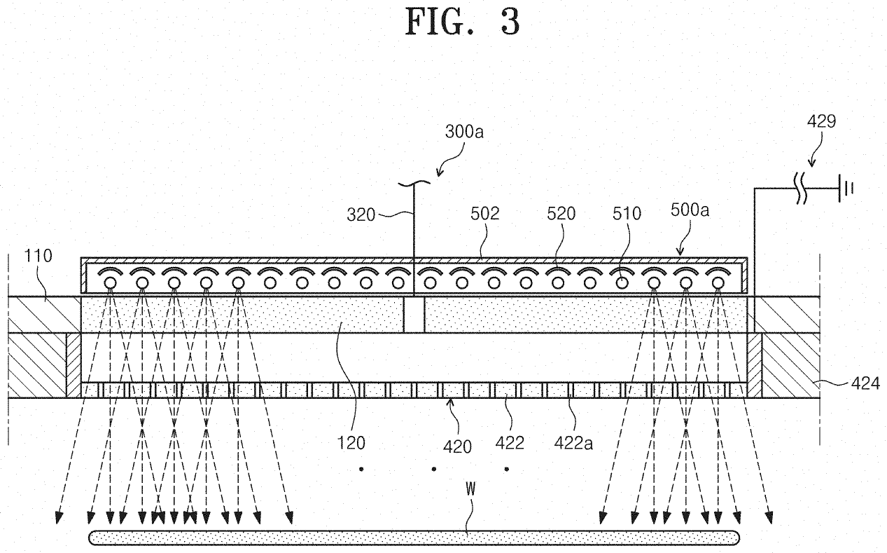

FIG. 3 is a view illustrating a heating unit illustrated in FIG. 2.

Referring to FIG. 2 and FIG. 3, the heating unit 500a may be disposed above the transparent window 120 to face the top electrode 420. The heating unit 500a may include a housing 502, IR lamps 510, and reflective covers 520. The IR lamps 510 emit a light energy, and the light energy may pass through the window 120 and the top electrode 420, thereby arriving at and heating the substrate W. The substrate may be quickly heated by the light energy.

For the plasma treatment in the substrate treating apparatus 10a having the above-described configuration, when the gas supply unit 300a supplies the process gas, the process gas is sprayed through the shower head 422 in the process chamber 100a. In this case, the plasma is generated in the process chamber 100a, and a plasma process may be performed. Furthermore, when the plasma treatment process proceeds, the substrate may be rapidly heated by the IR lamps 510 of the heating unit 500a. In this way, by providing the top electrode 420 as a transparent electrode, the heating unit 500a for heating the substrate may be disposed outside the process chamber 100a. In addition, since the heating unit 500a is provided outside the process chamber 100a, maintenance (lamp replacement, output capacity changing, etc.) of the heating unit 500a may be facilitated and damage caused by the plasma may be prevented.

In the present embodiment, the top electrode was described with a showerhead type structure as an example, but the inventive concept is not limited thereto.

Although the etching process is performed using the plasma in the embodiment, the substrate treatment process is not limited thereto, and may be applied to various substrate treatment processes using a plasma, for example, a deposition process, an ashing process, and a cleaning process. Also, in this embodiment, the plasma generating unit is described in a structure provided as a capacitive coupled plasma source. However, unlike this, the plasma generating unit may be provided as inductively coupled plasma (ICP). The inductively coupled plasma may include an antenna. In addition, the substrate treating apparatus may additionally include a plasma boundary limiting unit. The plasma boundary limiting unit may be provided in, for example, a ring shape, and may be provided to surround a discharge space to suppress the plasma from escaping to the outside thereof.

The effects of the inventive concept are not limited to the above-mentioned effects, and the unmentioned effects can be clearly understood by those skilled in the art to which the inventive concept pertains from the specification and the accompanying drawings.

Although the preferred embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

1. A substrate treating apparatus comprising:
a chamber having a treating space therein;
a support unit placed within the treating space and supporting a substrate; and
a plasma generating unit for generating a plasma from a process gas supplied to the treating space, and
wherein the plasma generating unit comprises:
a first electrode; and
a second electrode facing the first electrode, the second electrode made of a material capable of transmitting electromagnetic waves.

2. The substrate treating apparatus of claim 1 further comprising a heating unit for heating the substrate.

3. The substrate treating apparatus of claim 2, wherein the heating unit comprises a heating device using a thermal radiation.

4. The substrate treating apparatus of claim 3, wherein the heating device is any one of an IR lamp, a flash lamp, a laser, or a microwave.

5. The substrate treating apparatus of claim 3, wherein the second electrode is provided at a top wall of the chamber, the heating unit is provided above the top wall of the chamber, and the top wall is made of a material capable of transmitting electromagnetic waves.

6. The substrate treating apparatus of claim 5, wherein the second electrode is provided as a showerhead type with a through-hole for supplying a reaction gas onto the substrate placed on the support unit.

7. The substrate treating apparatus of claim 1, wherein the second electrode is made of any one of an ITO (Indium Tin Oxide), an MnO (Manganese Oxide), a ZnO (Zinc Oxide), an IZO (Indium Zinc Oxide), an FTO, an AZO, a graphene, a CNT (Carbon Nano Tube), a metal nanowire, or a PEDOT-PSS.

8. A substrate treating apparatus comprising:
a chamber wherein a plasma reaction process is performed;
a support unit provided at a bottom side within the chamber, holding a substrate thereon, and including a first electrode;
a second electrode provided at a top side of the chamber for generating an electric field for a plasma reaction process within the chamber; and
a power supply means for applying an RF power to the second electrode and/or the first electrode for generating an electric field between the second electrode and the first electrode;
wherein the second electrode is made of a material capable of transmitting electromagnetic waves.

9. The substrate treating apparatus of claim 8 further comprising a heating unit for heating the substrate.

10. The substrate treating apparatus of claim 9, wherein the heating unit comprises a heating device using a thermal radiation.

11. The substrate treating apparatus of claim 10, wherein the heating device is any one of an IR lamp, a flash lamp, a laser, or a microwave.

12. The substrate treating apparatus of claim 8, wherein the second electrode is provided at a top wall of the chamber, and the heating unit is provided above the top wall of the chamber.

13. The substrate treating apparatus of claim 12, wherein the top wall is made of a material capable of transmitting electromagnetic waves.

14. The substrate treating apparatus of claim 12, wherein the second electrode is made of any one of an ITO (Indium Tin Oxide), an MnO (Manganese Oxide), a ZnO (Zinc Oxide), an IZO (Indium Zinc Oxide), an FTO, an AZO, a graphene, a CNT (Carbon Nano Tube), a metal nanowire, or a PEDOT-PSS.

15. The substrate treating apparatus of claim 13, wherein the second electrode is provided as a showerhead type with a through-hole for supplying a reaction gas onto the substrate placed on the support unit.

16. A substrate treating apparatus comprising:
a chamber having a top wall with a transparent window and providing a plasma treating space;
an electrostatic chuck provided at a bottom side of the plasma treating space, electrostatically chucking a substrate and serving as a bottom electrode;
a shower-head placed below the transparent window of the top wall and above the electrostatic chuck, having a through-role for supplying a reaction gas onto the substrate placed on the electrostatic chuck, and serving as top electrode; and
a heating unit placed above the transparent window of the top wall and providing a light energy for heating the substrate;
wherein the showerhead is made of a material capable of transmitting electromagnetic waves provided from the heating unit.

17. The substrate treating apparatus of claim 16, wherein the showerhead is made of any one of an ITO (Indium Tin Oxide), an MnO (Manganese Oxide), a ZnO (Zinc Oxide), an IZO (Indium Zinc Oxide), an FTO, an AZO, a graphene, a CNT (Carbon Nano Tube), a metal nanowire, or a PEDOT-PSS.

18. The substrate treating apparatus of claim 16, wherein the heating device is any one of an IR lamp, a flash lamp, a laser, or a microwave.

19. The substrate treating apparatus of claim 16, further comprising a power supply means for applying an RF power to the electrostatic chuck and/or the shower head for generating an electric field therebetween.

20. (canceled)
